(19) United States
(12) Patent Application Publication
(10) Pub. No.: US 2005/0168947 A1
(43) Pub. Date: Aug. 4, 2005

(54) Chip packaging module with active cooling mechanisms

(76) Inventors: Lawrence Shungwei Mok, Brewster, NY (US); Leena Paivikki Buchwalter, Hopewell Junction, NY (US); Stephen Leslie Buchwalter, Hopewell Junction, NY (US)

Correspondence Address: Alvin J. Riddles, Candlewood Isle, Box 34, New Fairfield, CT, 06812, US

(21) Appl. No.: 10/733,672

(22) Filed: Dec. 11, 2003

(51) Int. Cl. H05K 7/20; H02B 1/00

(52) U.S. Cl. 361/698; 361/678

(57) ABSTRACT

The invention is directed to structure and methods of improving the cooling capacity of chip packaging modules. The chip packaging module has a substrate with thin-film wiring on one side and grooves or channels etched on one or both sides where coolant pumps are embedded. The coolant pumps are used to enhance the liquid flowing inside the module. The coolant flows through the chips within the vias in the chips or around the chips when the chips do not have vias. Both cooling modes, single or two-phase modes can be adopted in the module.

### FIELD OF THE INVENTION

The invention is in the field of heat dissipation from semiconductor chips where those semiconductor chips are packaged in a modular housing and in particular to fluid enhanced heat transfer within the housing.

### BACKGROUND AND RELATION TO THE PRIOR ART

It is well known that the power and power density of semiconductor chips are increasing rapidly. The current approach to packaging such higher power chips becomes inadequate because the heat generated on the active side of the chip has to pass through the chip, the chip-to-package interface, the package cover, and then to the heat sinking device. The heat transfer path is not efficient enough. A need is becoming apparent that a new chip packaging approach having a more efficient heat transfer will be required.

There has been some work in the art in chip packaging where chips are thinned to thicknesses even less than about 100 micrometers and the use of such thinned chips in systems that combine electrical and mechanical components in a single chip technology that has come to be known in the art by the acronym MEMS (Micro-Electro-Mechanical-Systems).

### SUMMARY OF THE INVENTION

In accordance with the invention, the heat generated in a chip, is transferred, out of the system through a highly efficient active cooling mechanism involving a liquid, a vapor or both coolant media. The active cooling mechanism of the invention brings the liquid or vapor or both heat transfer media, close to the chip, and passes the heat transferring medium to a location in the module for conventional heat dissipation away from the module. A coolant pumping mechanism that moves the coolant is incorporated at the chip level or on a substrate. The active cooling mechanism of the invention permits single phase coolant heat transfer and two phase, involving liquid and vapor phases, heat transfer in various packaging configurations.

### BRIEF DESCRIPTION OF THE DRAWINGS

The drawings are depictions of the structural and fluid flow conditions. For purposes of clarity, only major components are drawn in these figures and they, including the gear pumps, are not drawn to scale

FIG. 1 is a cross-sectional view of a multichip type module employing a built in active heat transfer liquid flow cooling mechanism.

FIG. 2 is an expanded view of a portion of the module of FIG. 1 showing the liquid flow path.

FIG. 3 is a simplified three dimensional view of an illustrative thin-film type substrate with embedded liquid pumps.

FIG. 4 is a further expanded view of a thin film type liquid pump for use in the invention wherein the gear teeth shaped pump blades have magnetization.

FIG. 5 is a view from a position below that of FIG. 4 showing electrical winding coils that are embedded in the thin-film type substrate.

FIG. 6 is a three dimensional view of a silicon circuitry substrate with an example four chips soldered in place.

FIG. 7 is a cross-sectional view of a multichip module with an active cooling chamber for chips and not employing through holes through the actual chip components.

FIG. 8 is a cross-sectional view of a multichip module with an active cooling chamber between chips and a common heat sink,

FIG. 9 is a schematic view of a chip cooling mechanism using microelectromechanical system (MEMS) type pumps built on the heat radiating side or back side of the chip, and,

FIG. 10 is a schematic view of a chip cooling mechanism using microelectromechanical system (MEMS) type pumps built on an adjacent substrate.

### DESCRIPTION OF THE INVENTION

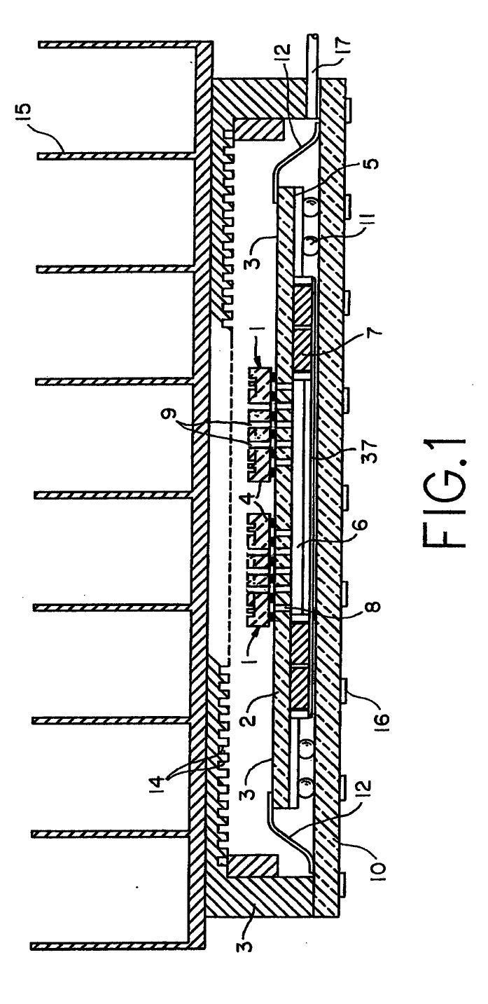

The invention is illustrated in connection with a common in the art multichip type module with the addition of the invention of a built in active cooling mechanism as is shown in a cross-sectional view in FIG. 1 and subsequent figures.

Referring to FIG. 1, thin film chips labelled 1, of which two are shown, are mounted on an insulating or semiconducting supporting substrate labelled 2 made of silicon, ceramic or other such material with or without thin-film wiring layers, not shown, on the upper surface 3. The chips 1 themselves, have a surface through which contacts are made, an adjacent heat generating region and a heat radiating or back side surface with grooves for increased surface area for improved heat transfer. The distance between the heat generating region and the heat radiating surface attenuates heat transfer away from the chip. A minimum thickness of the order of 50-100 micrometers between the heat generating region and the heat radiating surface is preferred for heat transfer efficiency. Wafer thinning to these dimensions is well known in the art.

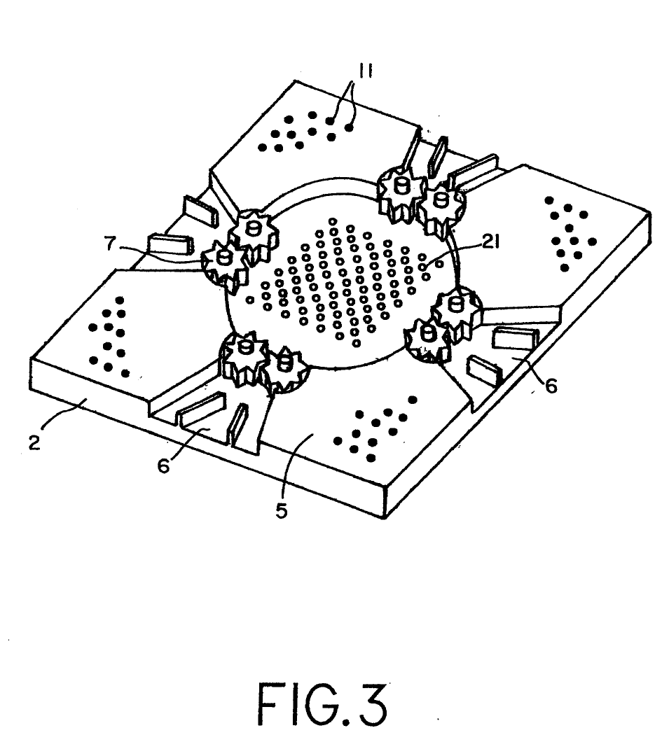

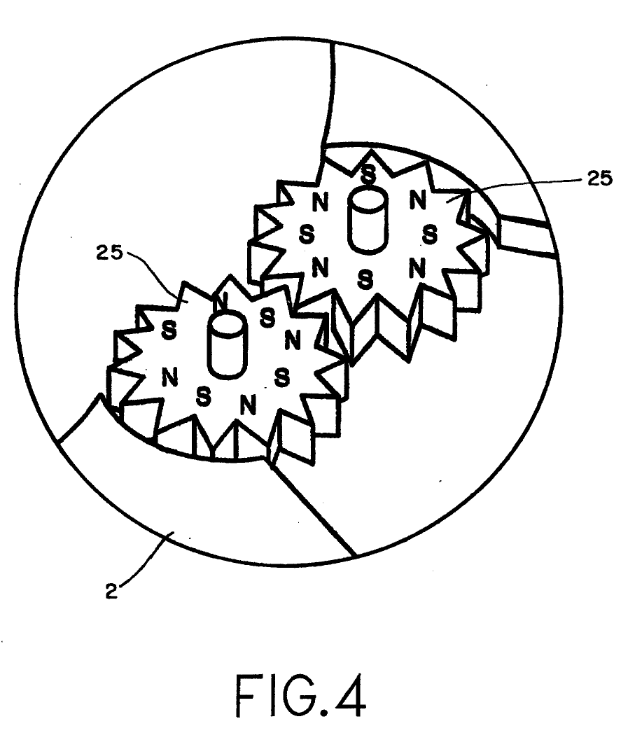

Standard solder ball connections 4 are used to join the chip 1 to the substrate 2 as illustrated in FIG. 1. On the under side 5 of the substrate 2 there are fluid conveying etched grooves 6 and gear pumps 7 that have been embedded in the structure during it's assembly. There is a support cover 37 for the gear pumps 7. The gear pumps 7 that are shown in the FIGS. 3 and 4 are simply as an example; any other type of pump design can be used. There are through holes 8 through the substrate 2 as well as through holes 9 through the chips 1. The thickness of substrate 2 is about 100 micrometers. The substrate 2 is mounted on the module substrate 10 using solder balls 11 in the middle area and optionally flexible cables 12 on the perimeters. A cap 13 of metal or another such material serves as the upper cover of the module housing having a heat transfer region of grooves 14 in its inner surface to improve efficiency in extracting heat from the coolant circulating within the housing. an external heat sink 16 is soldered to the outer surface of the cap 13 for the module and to the substrate or board 10 thus completing the fluid containing housing and heat transferring structure.

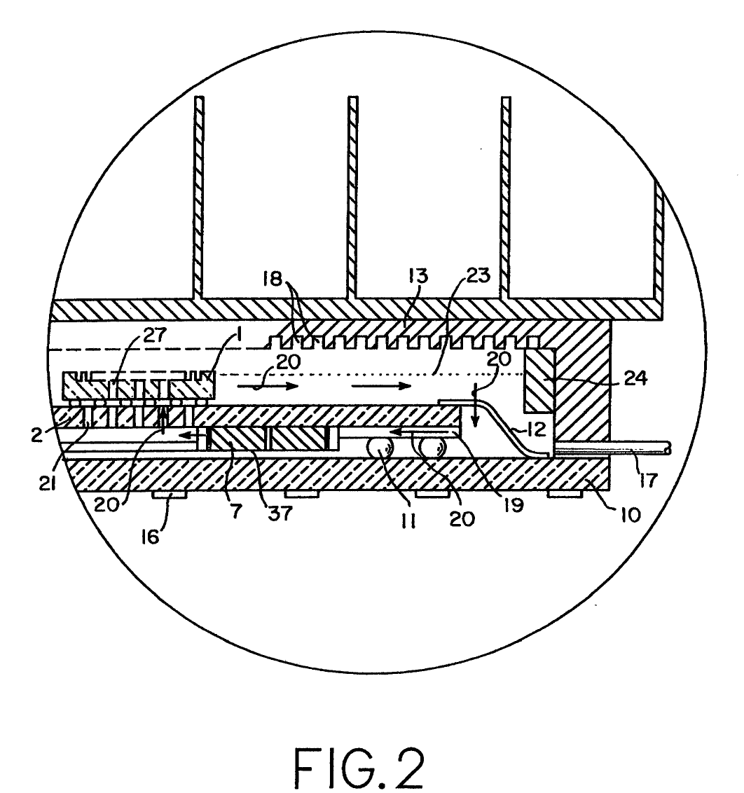

Connection pads 16 on the under surface of the module board 10 serve as the signal and power connections to the other portions of the system. The fill port 17 is used to evacuate and fill the cooling chamber. The invention is further illustrated in connection with the standard in the art multichip type module with the addition of the invention including the example built in active cooling mechanism in an enlarged depiction view in FIG. 2. The enlarged view of FIG. 2 is a cross sectional depiction of the module at the portion including the fill port 17. The reference numerals are the same as those in FIG. 1 for like elements and the fluid flow paths are indicated.

Referring to FIG. 2 in the example active cooling mechanism there are two possible cooling modes inside the chip module: a first one involves single phase liquid cooling in which the liquid enclosed inside the module will remain in liquid form and will not change phase during normal operation; a second one involves two-phase cooling in which the liquid enclosed inside the module will evaporate on the surfaces of the chips 1 and substrate 2 and condense on the inner surface and grooves 18 of the metal cap 13. In the single-phase cooling mode, the module is filled with liquid completely through the fill port 17. An example coolant material for single phase cooling is water and an example coolant material for two phase cooling is water at reduced pressure or a fluorocarbon fluid. Any heat transfer fluid that is compatible with the materials can be employed. Where water is used a thin insulating coating on the solder balls and wires is beneficial.

The embedded gear pumps 7 will force the liquid which moves, in the directions indicated by the arrows 20, through the fluid transport grooves 19 in the substrate 2, the grooves 18 in the metal cap 13 as well as the holes 21 through the substrate 2 and 22 in the chip 1. In operation, heat generated by the chips 1 in single phase one type of cooling, will transfer to the moving liquid and then to the metal cap 13. In the phase two type of cooling, the module is partially filled with liquid to a line depicted dotted and labelled element 23. The liquid will vaporize on the surfaces of the chips 1 and the silicon substrate 2. The vapor then flows toward the metal cap 13 where it will condense back to liquid. The capillary force of the liquid in the grooves on the cap 13, and the substrate 2 as well as the holes 22 through the chips and holes 21 through the substrate 2 will pull the liquid back to the substrate 2 and the chips 1. The embedded gear pumps 7 will assist further in moving the liquid. Optional wick members 24 near the perimeters of the metal cap 13 will help to bridge the gap between the metal cap 13 and the substrate 2. The arrows 20 depict the typical liquid flow paths.

Some assembly comments relating to FIGS. 1 and 2 are as follows.

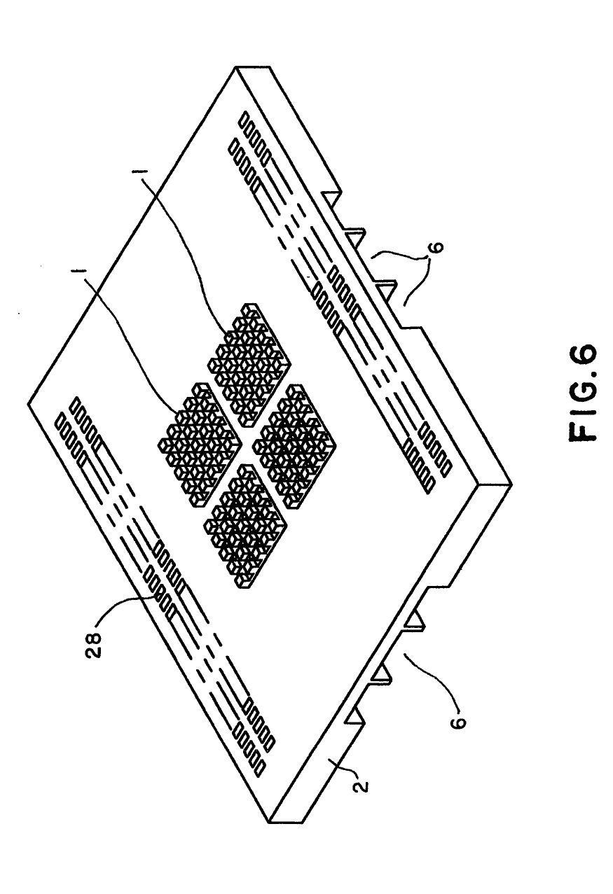

The substrate 2 will have thin film circuitry deposited, through holes 8 etched, and grooves 6 etched first. The gear pumps 7 are then mounted on the under side of the substrate 2 with a cover 37. The chips 1 are soldered on the designated locations on the upper side of the substrate 2 by the conventional solder ball reflow technology. The flexible cables 12 are bonded on the connection pads 28 (in FIG. 6) to the substrate, which is later mounted on the module substrate 10. After the module assembly, the other end of the flexible cables 12 will be soldered on the connection pads on the module substrate 10. The cap 13, which has grooves 18 on the innner surface and optional wick members 24 is then mounted on the module substrate 10. The finished module wil then be examined and tested. If all the tests are passed, the module will be evacuated and filled with a determined amount of coolant inside the cavity of the module through the fill port 17.

In FIG. 3 there is shown a simplified depiction of a three dimensional view of the underside 5 of the substrate 2. Referring to FIG. 3 in this view there are four embedded gear pumps 7. The etched channels and diverters 6 perform the function of guiding the liquid flowing into and out of the gear pumps 7. The holes 21 through the substrate 2 at the center serve as channels for the liquid to pass through to the chips 1, not visible in this view. The solder balls 11 on the substrate 2 are for electrical signal and power connections.

In FIG. 4 there is depicted an enlarged view of example gear pump 7 teeth 25 which serve as blades. In the invention the gear teeth 25 are locally magnetized in alternating poles, North (N) and South (S).

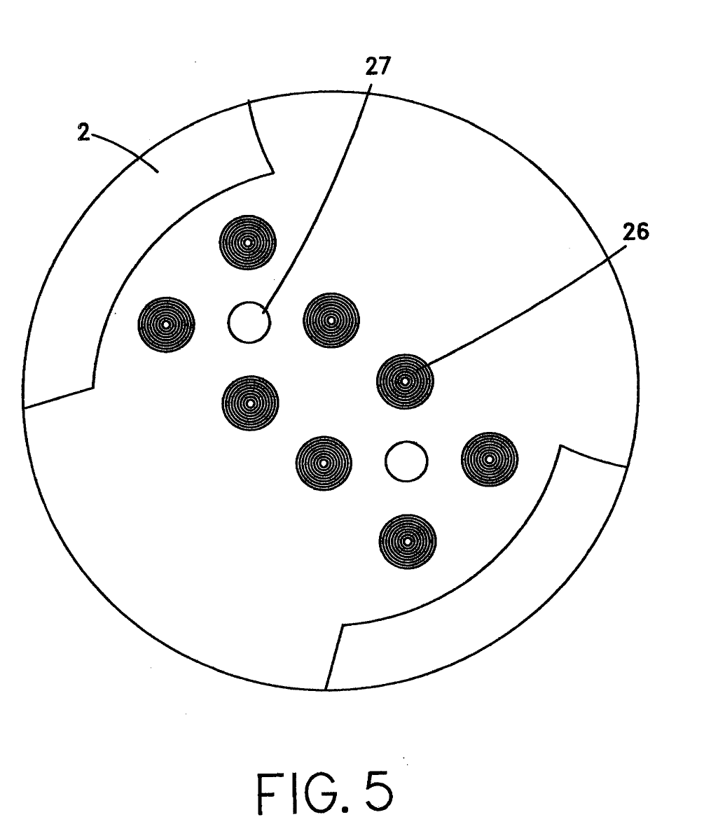

In FIG. 5 there is shown a depiction of an enlarged view of the substrate 2 where the area occupied by the gear pump 7 has been removed to show electrical winding coils 26 in the substrate 2. The coils are relatively equally positioned around a shaft opening 27 and are wired to create the needed magnetic fields to drive the gear pump blades to rotate around the shaft opening 27. The shaft of the gear pump is inserted into the opening 27 in the substrate 2. The opening 27 can be coated with hard metal or diamond films to make it more durable against the frictional wear and tear of the rotational shaft of the gear pump 7.

Assembly comments concerning FIGS. 3, 4, and 5.

The under side of the substrate 2 has grooves 6, solder balls 11, and through holes 21 built in. The electrical winding coils 26 made of thin film layers consisting of several alternating layers of metal and insulation materials, which are not shown in detail in FIG. 5. The coils 26 are then connected to the selective solder balls 11. The gears 25 are premagnetized in the pattern similar to the one shown in FIG. 4. There are magnetic sensers such as Hall effect sensors, which are not showh in FIG. 3, that are embedded in the substrate 2 near the gear pumps to monitor the gear positions. The gear position signal will be later used by the control circuitry outside of the module to energize the winding coils 26 and drive the gears accordingly.

In FIG. 6 there is shown a three dimensional view of the thin film circuitry substrate of the invention with the chips positioned. Referring to FIG. 6, an example four chips 1 are mounted on the top surface of the substrate 2. There are connection pads 28 on the perimeter of the substrate 2 for connecting electrical signals and power to the module board 10 via the flexible cables 12 not shown in this Figure but which are shown in FIGS. 1 and 2. The fluid conveying grooves are labelled 6.

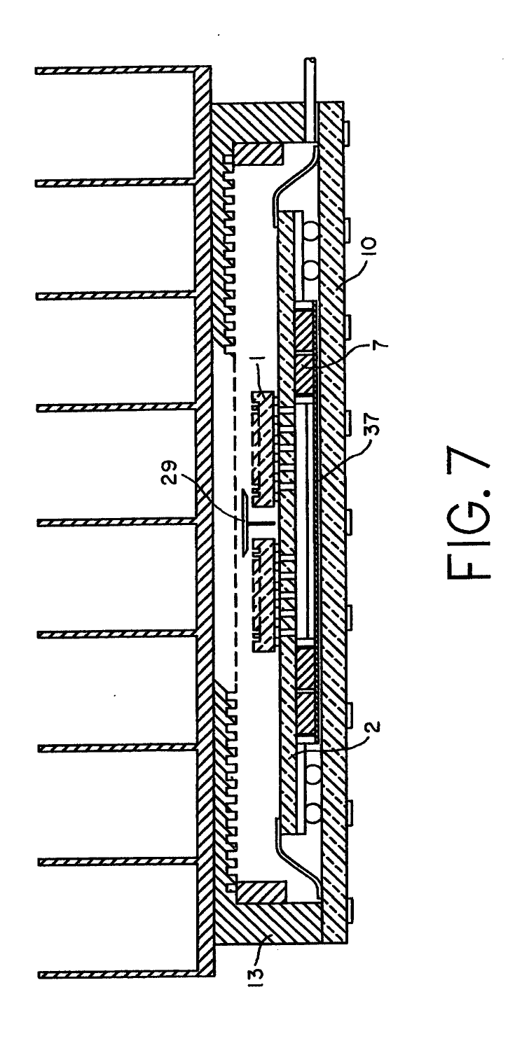

Overview comment with respect to FIG. 7.

This is similar to FIGS. 1 and 2 except that the chips used in the module do not have through holes 9 through the chips.

In FIG. 7 an embodiment is illustrated that provides coolant diversion that is useable to direct the coolant into a particular path. Referring to FIG. 7 a coolant diverter element labelled 29 is placed among chips 1 to direct the liquid coolant flowing across the heat radiation side of the chips 1. This embodiment allows conventional chips to be used since no through-vias on the chip are required. All other major components are as is shown in the other Figures.

In the two embodiments of FIGS. 6 and 7 the liquid coolant must not be electrically conductive and should be chemically compatible with the silicon chips, any metals and dielectrics used inside the chip packaging module. Alternatively, a thin passivation layer such as the material available in the art under the trademark PARYLENE or other conformal coating can be deposited on all of the surfaces inside the module to separate the liquid coolant from the chips and electrical circuitry.

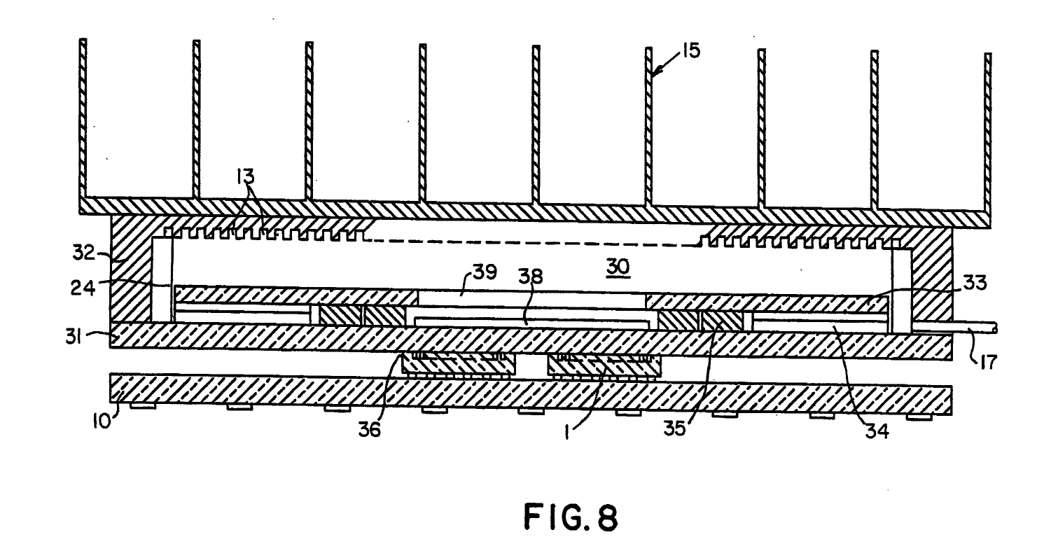

In FIG. 8 there is shown a cross-sectional view of a multichip module wherein there is an active cooling chamber provided and the chips are attached to a common heat sink. Referring to FIG. 8 the liquid coolant is placed inside a separate chamber 30 which is mounted above the chips 1. In this embodiment, the liquid coolant is totally separated from the electrical parts of the module. The cooling chamber 30 is made up of a base plate 31 and a top cover 32. The substrate 33 in this cooling chamber embodiment is similar to the substrate 2 in FIG. 1, in that it has etched channels 34 and gear pumps 35 embedded, except that there is an opening 39 at the center. The cooling chamber 30 acts as a heat transfer and spreading medium to serve as a thermal dissipation bridge from the chips 1 to the heat sinking device 15. There are etched channels or wicks 38 which act as an evaporator for the coolant chamber 30. Both the single and the two-phase cooling modes described earlier can be applied to this coolant chamber 30 as well. In the two-phase cooling mode, the chamber acts like a flat vapor chamber but with embedded gear pumps to enhance the coolant movement inside the chamber. As a result, this pump-assisted vapor chamber has better heat transfer characteristics than a conventional vapor chamber. The thermal interface pads 36 serve as a thermal dissipation bridge from the chips 1, through the coolant chamber to the heat sinking device 15.

Assembly and overview comments with respect to FIG. 8.

This sets forth the principles for a stand alone actively pumped cooling chamber. The substrate 33 is similar to those described in FIGS. 1 and 2 except that there are no thin film circuitry layers and there is a window opening 39 at the center. The gear pumps 35 and grooves 34 are on the underside and sandwiched between the substrate 33 and the bottom plate 31. There is an evaporator 38 bonded at the center of the inner surface of the bottom plate 31 facing the window opening 39 on the substrate 33. Once the substrate 33 is mounted on the bottom plate 31, the cap 32 with the grooves 13 and wicks 24 is bonded to the bottom plate 31. The cooling chamber 30 is now complete, is then evacuated and filled with a predetermined amount of coolant through the fill port 17 which is permanently sealed afterward. The electrical connections from the winding coils and the gear position sensors on the substrate 33 are not shown in the figure. The actively pumped cooling chamber assembly is positioned on top of the chips 1 which have been soldered on the module substrate 10 with the thermal interface pads 36 in between. The heat sinking device 15 is brought into contact with the active cooling chamber for dissipating the heat from the chamber.

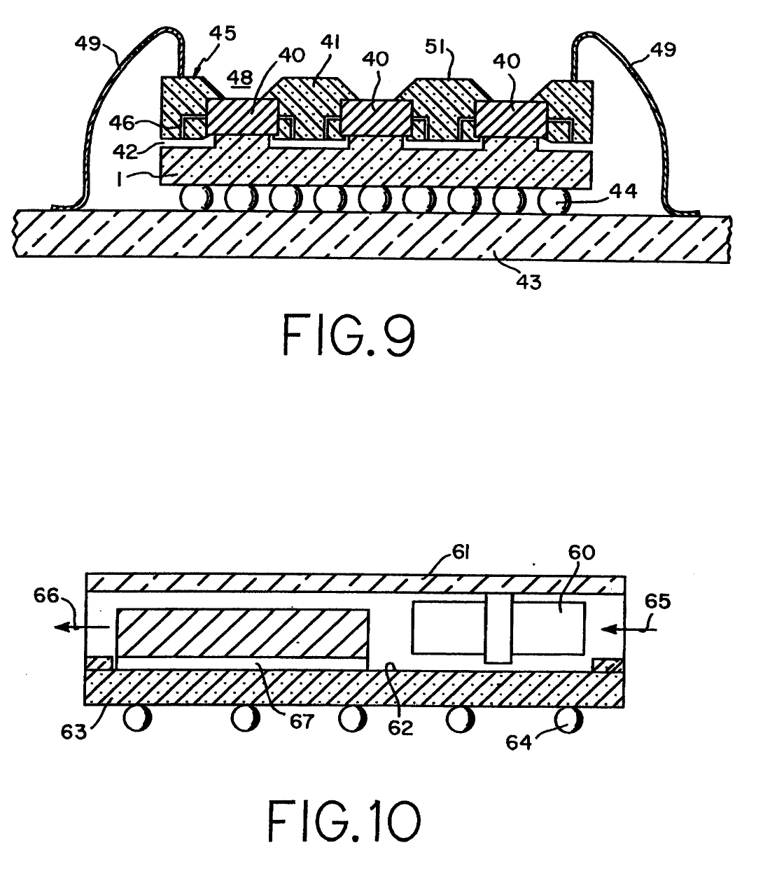

In FIG. 9 there is illustrated another embodiment of the invention in which microelectromechanical system (MEMS) pumps are embedded on the back side of the chip. The metal cover 13 of the module is not shown in the figure. The MEMS pumps 40 of which three are shown, are embedded in a silicon substrate 41 which is bonded on the backside of the chip 1 which has coolant channels 42 etched in it. The chip 1 is mounted on a module board 43 using solder balls 44.

Referring to FIG. 9, there is illustrated another embodiment of the invention in which microelectromechanical system (MEMS) type pumps are embedded on the back side of the chip 1. The metal cover 13 of the module is not shown in the figure. The MEMS type pumps 40, of which three are shown, are embedded in a silicon substrate 41 which is bonded on the back side of the chip 1 which, has coolant channels 42 etched in it. The chip 1 is mounted on a module board 43 using conventional solder balls 44.

FIG. 9 shows only one chip with MEMS pumps 40 on the back side. The following general procedures are used to produce chip stack. The Si wafer 1 is bonded to a handler wafer using reversible adhesive joining, if necessary, as taught by Adler et al, in the Proceedings of the 4th Int'l Conf. Adhesive Joining and Coating Technology, in Electronics Manufacturing, 20-23, (2000), and C. Landesberger et al., Int. Symp. Adv. Packaging Mater., 92-97, 2001. The Si wafer is thinned as taught in U.S. Pat. No. 6,455,398 to the desirde thickness even down to 10-25 um, though 50-100 um thickness may be preferred. Coolant channels 42 are etched into the thinned Si wafer 1 back side using KOH, TMAH, and/or dry silicon etching processes known to those skilled in the art. MEMS pumps 40, of the type shown in FIG. 3 or a different one are built using a second Si wafer 1 with required circuitry 51 for their operation. The second Si wafer is labelled 45 in FIG. 9, with the MEMS pumps 40 with vias 46 aligning to the coolant channels 42 etched into the thinned silicon wafer 45 and is bonded to the thinned silicon wafer 45 thus enclosing the coolant channels. Wafer bonding schemes taught in U.S. Pat. Nos. 6,391,673, 6,328,841, and 6,455,398 can be used. After bonding the second Si wafer 45 is thinned. The electrical connection 49 to the MEMS pump circuitry in the second Si wafer is done using the high aspect ratio through wafer electrical interconnect (TWEI) technique such as is described in an article by Ok et al. in Proc. IEEE ECTC, (232-237), 2002. Standard integrated circuit via metallization and wirebond pads are deposited followed by definition of coolant access holes 48 to allow coolant access to the MEMS pumps 40. The device wafer stack is released from the handler wafer using appropriate release techniques as taught for example in the previously discussed Landesberger et al publication, in the International Symposium on Advance Packaging Materials, 92-97, 2001. Via connection surfaces are cleaned and C4 balls 44 are deposited using the well known techniques in the art. A chip dicing by wafer thinning technique is used to separate chip stacks from each other as taught by G. Klink et al. published in the Proceedings of the IEEE ECTC, (2001).

The operation to separate the chip stacks from each other can be accomplished by a variation of the chip dicing by thinning technique described in the publication by Klink et al. published in the Proceedings of the IEEE ECTC, (2001). In this case the dicing channels are patterned into the IC side of the first wafer during the IC processing, or they are patterened from the backside of the thinned first wafer while on the handler wafer. The dicing channels are replicated on the second wafer with the MEMS pumps 40 after it has been bonded onto the first Si wafer. Thus, when the carrier wafer is removed, the chip stacks are released and ready for C4 processing, bonding and wirebonding.

An alternative procedure for building the MEMS pump circuitry 51 into the second Si wafer with the MEMS pumps 40, is to build the circuitry into the first wafer 1 with the chips. The circuitry is then connected to the MEMS pumps 40 via wirebonding such as 49 and ball connections such as 44 to the module board 43.

Assembly comments with respect to FIG. 9.

The wafer containing chip 1 will be thinned down to a predetermined thickness and have grooves etched on it. Another wafer 45 has MEMS type pumps 40 and the required circuitry 51 built on it. These two wafers will be then bonded to each other such that the vias 46 will align to the coolant channels 42. The resulting wafer stack is to be diced into pieces and each piece will contain a chip with several MEMS pumps on the back side.

Another illustration of the applicability of the principles of the invention is illustrated in FIG. 10 through the positioning of the MEMS pump in close proximity to the heat radiating surface of the chip.

Referring to FIG. 10, a gear pump 60 similar to element 7 in FIGS. 1 and 2 is mounted on a substrate 61 positioned parallel to and in close proximity to the heat radiating surface 62 of a chip 63. The ball contacts 64 connect the contacts, not shown, on the electrical contact side of the chip 63 to the external wiring not shown. The electrical wiring for the pump 60 follows the principles of FIGS. 3, 4, and 5 is not shown. The coolant flow follows the path indicated by arrows 65 to 66, passing through the grooves 67 on the heat radiating side of the chip 63.

Assembly comments with respect to FIG. 10.

The wafer containing chip 63 will have grooves 67 etched on the back side. The wafer then is diced into pieces. A gear pump similar to element 7 in FIGS. 1 and 2 is mounted on a substrate 61 and the completed assembly is bonded on to the top of the chip.

What has been described is the improvement in heat transfer out of a semiconductor electronics module package through the integration at the chip level of active coolant enhanced heat transfer with micro electromechanical structures fluid propulsion.

1. In the fabrication of an electrical apparatus modular system in which in each module of said system there is at least one semiconductor chip, each said chip having an essentially parallel; electrical contacting surface, a heat generating region adjacent to said contacting surface and a heat radiating surface; said at least one chip being arranged in a surrounding, fluid containing, housing for that module in said system; with an external portion of said housing being attached to a heat sink;
an improvement in transfer of heat that is generated within each said chip to a location that is away from said heat radiating surface of said chip,
comprising in combination:
maintaining a coolant level in said housing that immerses said chips to and including at least each said heat generating region of said chip, and,
providing means for moving a coolant fluid in a closed path within said housing serially over each heat radiating surface of each chip and over at least a portion of the interior surface of said housing corresponding to where said heat sink is attached to the outside surface of said housing.

2. The heat transfer improvement of claim 1 wherein said surrounding housing is a metal cap having an outside region soldered to a heat sink and having heat transfer grooves in said interior surface of said housing corresponding to where said heat sink is attached to the outside surface of said housing.

3. In the fabrication of an electrical apparatus modular system in which in each module of said system there is at least one semiconductor chip, each said chip having an essentially parallel; electrical contacting surface, a heat generating region adjacent to said contacting surface and a heat radiating surface; said at least one chip being arranged in a surrounding, fluid containing, housing for that module in said system; with an external portion of said housing being attached to a heat sink;
an improvement in transfer of heat that is generated within each said chip to a location that is away from said heat radiating surface of said chip,
comprising in combination:
maintaining a thin film type thickness dimension range of about 50 to 100 micrometers in each said chip between said contacting surface and said heat radiating surface, and,
providing means for moving a coolant fluid in a closed path within said housing serially over each heat radiating surface of each chip and over at least a portion of the interior surface of said housing corresponding to where said heat sink is attached to the outside surface of said housing.

4. The heat transfer improvement of claim 3 wherein said surrounding housing is a metal cap having an outside region soldered to a heat sink and having heat transfer grooves in said interior surface of said housing corresponding to where said heat sink is attached to the outside surface of said housing.

5. The heat transfer improvement of claim 4 wherein said surrounding housing is attached around the periphery to a module size circuitry bearing insulating board and is a sealed active coolant chamber.

6. The heat transfer improvement of claim 4 wherein all chips of said at least one chip are in contact with a thin film thickness type insulating substrate, said substrate serving as support for micro-electro-mechanically enhanced heat transfer apparatus.

7. The heat transfer improvement of claim 6 wherein said micro-electro-mechanically enhanced heat transfer apparatus is a fluid pump.

8. The heat transfer improvement of claim 7 wherein said micro-electro-mechanically enhanced heat transfer apparatus is a fluid pump.

9. The heat transfer improvement of claim 8 wherein said micro-electro-mechanically enhanced heat transfer apparatus is a magnetically responsive gear type fluid pump.

10. The heat transfer improvement of claim 9 wherein all chips of said at least one chip have the contacts in said contacting surface joined to circuitry on a second of two sides of a thin film thickness type insulating substrate, said substrate on the first of said two sides having a pump assembly in thin film thickness layers where thin film pumps draw coolant from a reservoir of coolant surrounding said chips and substrate, propelling said coolant through thin film passageways from the periphery of said substrate through holes in said thin film substrate and said chips and back to said reservoir and having contacts on said second of said two sides of said substrate that are joined to said circuitry on said insulating board.

11. The heat transfer improvement of claim 10 wherein all chips of said at least one chip have the contacts in said contacting surface joined to circuitry on a first of two sides of a thin film thickness type insulating substrate, said substrate on the second of said two sides having a pump assembly in thin film thickness layers where thin film pumps draw coolant from a reservoir of coolant surrounding said chips and substrate, propelling said coolant through thin film passageways from the periphery of said substrate through holes in said thin film substrate and said chips and back to said reservoir and having contacts on said second of said two sides of said substrate that are joined to said circuitry on said insulating board.

12. The heat transfer improvement of claim 10 wherein all chips of said at least one chip have the contacts in said contacting surface joined to circuitry on a second of two sides of a thin film thickness type insulating substrate, said substrate on the first of said two sides having a pump assembly in thin film thickness layers where thin film pumps draw coolant from a reservoir of coolant surrounding said chips and substrate, propelling said coolant through thin film passageways from the periphery of said substrate through holes in said thin film substrate and said chips and back to said reservoir and having contacts on said first of said two sides of said substrate that are joined to said circuitry on said insulating board.

13. The heat transfer improvement of claim 10 wherein all chips of said at least one chip have the contacts in said contacting surface joined to circuitry on an interior side of a module board, a first thin film thickness layer containing coolant fluid channels is in contact with the heat radiating surface of said chip, and a second thin film thickness layer containing MEMS type thin film pumps is positioned in contact with said first layer.

14. The process of providing actively pumped electrical apparatus comprising the steps of:
positioning at least one semiconductor chip, a substrate and a micro-electro-mechanical pump within a sealed housing containing a coolant fluid, in a physical relationship such that said coolant fluid is pumped over the heat generating surface of each said chip,
attaching said housing to a heat sink,
maintaining a coolant level in said housing that immerses said chips, and,
providing means for moving a coolant fluid in a closed path within said housing serially over each semiconductor chip and over at least a portion of the interior surface of said housing corresponding to where said heat sink is attached to the outside surface of said housing.

15. A MEMS type fluid pump comprising:
embedded conductive coils positioned in a circle surrounding an axle opening in a thin film thickness layer of insulating material,
a gear shaped rotary impeller member of thin film thickness attached to and surrounding an axle extending through said axle opening
said gear shaped rotary member having opposite pole magnetization on alternate teeth around the periphery thereof and,
a fluid directional control layer of thin film thickness having fluid guidance passageways extending from the periphery to said impeller.
